(19) United States
(12) Patent Application Publication
(10) Pub. No.: US 2026/0239903 A1
(43) Pub. Date: Aug. 13, 2026

(54) SEMICONDUCTOR SUBSTRATE AND MANUFACTURING METHOD OF SEMICONDUCTOR SUBSTRATE

(71) Applicant: Mitsubishi Electric Corporation, Tokyo (JP)

(72) Inventor: Kazuki TAGUCHI, Tokyo (JP)

(73) Assignee: Mitsubishi Electric Corporation, Tokyo (JP)

(21) Appl. No.: 19/449,772

(22) Filed: Jan. 15, 2026

(30) Foreign Application Priority Data
Feb. 13, 2025 (JP) 2025-021347

(51) Int. Cl. H10P 30/20; H10P 30/28; H10P 70/00

(52) U.S. Cl. CPC H10P 30/222; H10P 30/28; H10P 70/20

(57) ABSTRACT

The manufacturing method of a semiconductor substrate includes a mounting step, an ion implantation step, and an activation step. In the mounting step, a substrate body that has a front surface on which a front surface electrode is formed and a rear surface which faces front surface is mounted on a mounting stage with rear surface facing upward. In the ion implantation step, ion implantation is performed on rear surface of substrate body mounted on mounting stage from a first direction and a second direction symmetrical to the first direction at an angle of 45° or more and 84° or less with respect to rear surface to form an ion implantation layer. In the activation step, ions implanted into ion implantation layer are activated by performing a laser annealing treatment on ion implantation layer.

### CROSS REFERENCE TO RELATED APPLICATIONS

This non-provisional application is based on Japanese Patent Application 2025-021347 filed on Feb. 13, 2025 with the Japan Patent Office, the entire contents of which are hereby incorporated by reference.

### BACKGROUND OF THE INVENTION

### Field of the Invention

The present disclosure relates to a semiconductor substrate and a manufacturing method of the semiconductor substrate.

### Description of the Background Art

In a rear surface wafer process of IGBT (Insulated Gate Bipolar Transistor), a foreign substance may adhere to a semiconductor substrate before ion implantation is performed on a rear surface which faces a front surface on which a front surface electrode is formed. If the ion implantation is performed on the rear surface adhered with a foreign substance, an ion non-implanted region is formed under the foreign substance. This may cause a leakage current to occur when a voltage is applied.

Japanese Patent Laying-Open No. 2000-188082 discloses an ion implantation method for forming a buried oxide film layer that has no pinhole defect on a silicon (Si) wafer even if particles adhere to the wafer surface. In the ion implantation method, the Si wafer is tilted, and about a half of the total amount of ions is implanted into the Si wafer surface by using an oxygen ion beam. Thereafter, the oxygen ion beam is stopped, and the Si wafer is maintained at the original tilt angle. Then, the Si wafer is rotated around the center of the Si wafer, and the remaining half of the total amount of ions is implanted.

However, Japanese Patent Laying-Open No. 2000-188082 does not disclose a method of forming an ion implantation layer on a rear surface of the semiconductor substrate.

### SUMMARY OF THE INVENTION

The present disclosure has been made to solve the aforementioned problems, and an object of the present disclosure is to provide a semiconductor substrate and a manufacturing method of a semiconductor substrate capable of preventing an ion non-implanted region from being formed on a rear surface so as to prevent a leakage current from occurring.

The manufacturing method of a semiconductor substrate according to the present disclosure includes a mounting step, an ion implantation step, and an activation step. In the mounting step, a substrate body that has a front surface on which a front surface electrode is formed and a rear surface which faces the front surface is mounted on a mounting stage with the rear surface facing upward. In the ion implantation step, an ion implantation layer is formed by performing ion implantation on the rear surface of the substrate body from a first direction and a second direction symmetrical to the first direction at an angle of 45° or more and 84° or less with respect to the rear surface. In the activation step, ions implanted into the ion implantation layer are activated by performing a laser annealing treatment on the ion implantation layer.

According to the manufacturing method of a semiconductor substrate of the present disclosure, it is possible to prevent an ion non-implanted region from being formed on the rear surface so as to prevent a leakage current from occurring.

The foregoing and other objects, features, aspects and advantages of the present invention will become more apparent from the following detailed description of the present invention when taken in conjunction with the accompanying drawings.

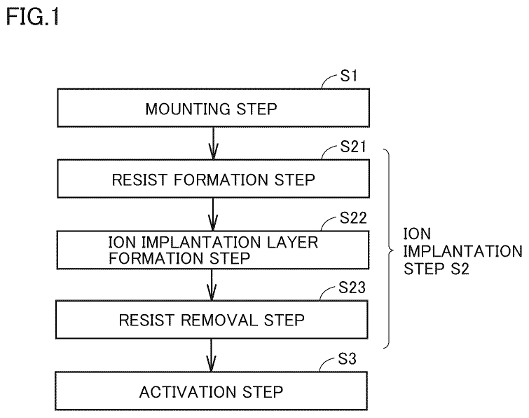

FIG. 1 is a flowchart illustrating a manufacturing method of a semiconductor substrate according to a first embodiment.

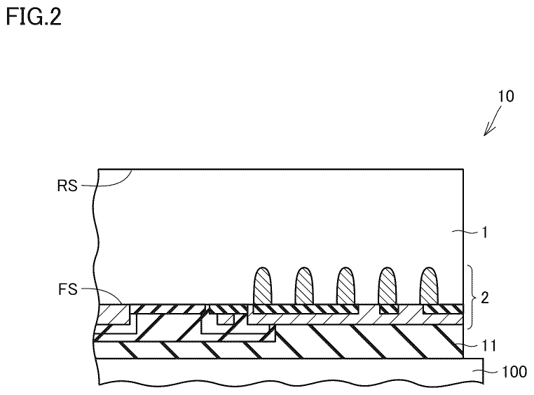

FIG. 2 is a cross-sectional view schematically illustrating a mounting step of the manufacturing method of a semiconductor substrate according to the first embodiment.

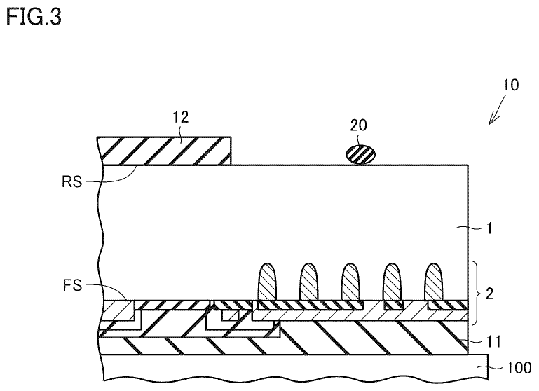

FIG. 3 is a cross-sectional view schematically illustrating a resist formation step included in the ion implantation step of the manufacturing method of a semiconductor substrate according to the first embodiment.

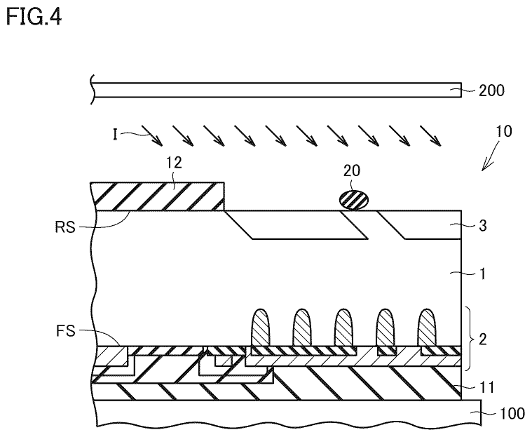

FIG. 4 is a cross-sectional view schematically illustrating that ion implantation is performed from a first direction in the ion implantation step of the manufacturing method of a semiconductor substrate according to the first embodiment.

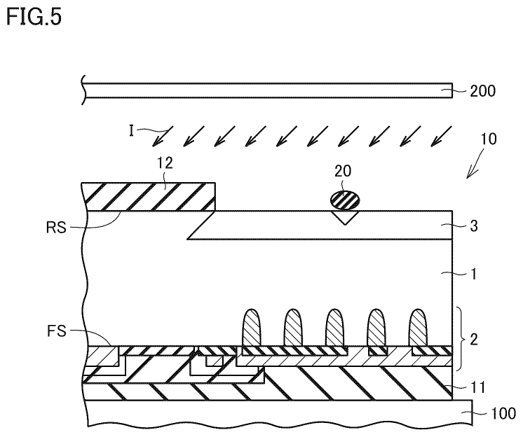

FIG. 5 is a cross-sectional view schematically illustrating that ion implantation is performed from a second direction in the ion implantation step of the manufacturing method of a semiconductor substrate according to the first embodiment.

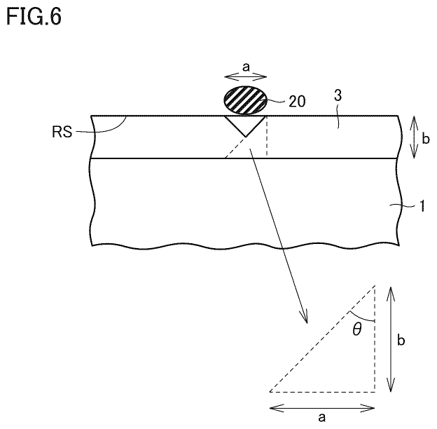

FIG. 6 is a schematic view illustrating an ion implantation angle in the ion implantation step of the manufacturing method of a semiconductor substrate according to the first embodiment.

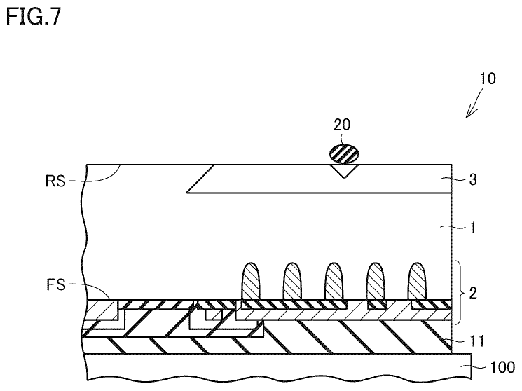

FIG. 7 is a cross-sectional view schematically illustrating a resist removal step included in the ion implantation step of the manufacturing method of a semiconductor substrate according to the first embodiment.

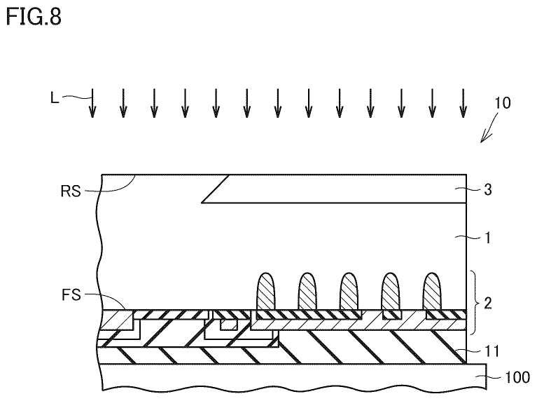

FIG. 8 is a cross-sectional view schematically illustrating an activation step of the manufacturing method of a semiconductor substrate according to the first embodiment.

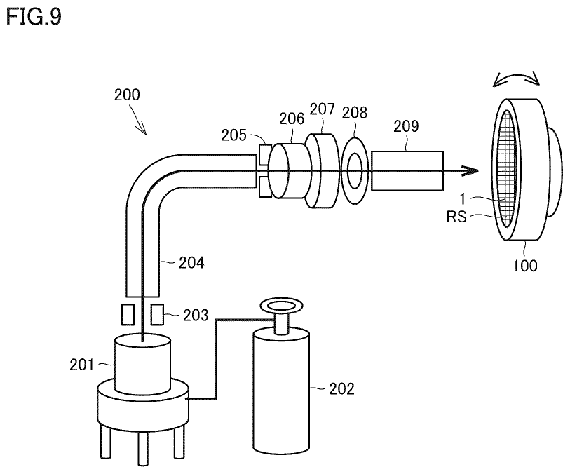

FIG. 9 is a perspective view schematically illustrating an ion implantation apparatus used in the manufacturing method of a semiconductor substrate according to the first embodiment.

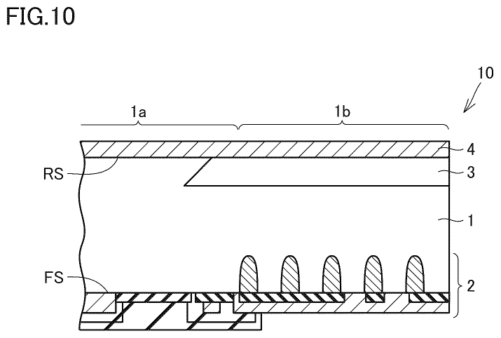

FIG. 10 is a cross-sectional view schematically illustrating the configuration of a semiconductor substrate according to the first embodiment.

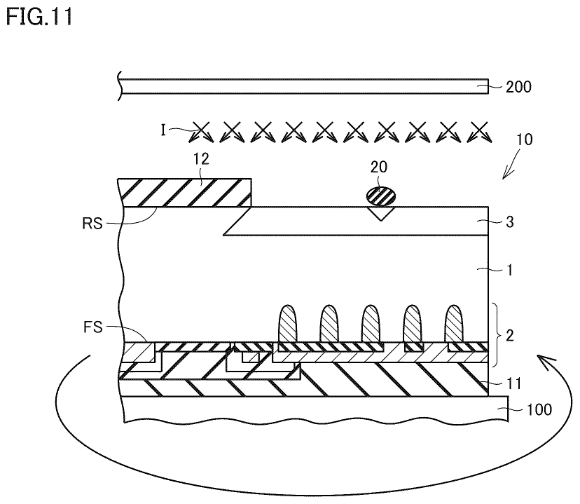

FIG. 11 is a cross-sectional view schematically illustrating that ion implantation is performed in an ion implantation step according to a modification of the manufacturing method of a semiconductor substrate according to the first embodiment.

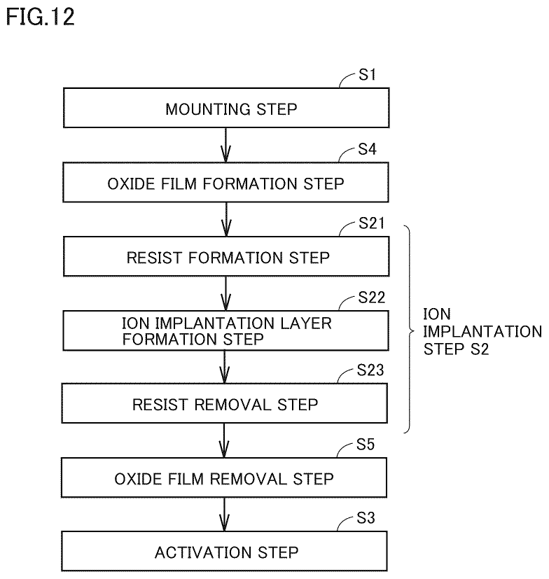

FIG. 12 is a flowchart illustrating a manufacturing method of a semiconductor substrate according to a second embodiment.

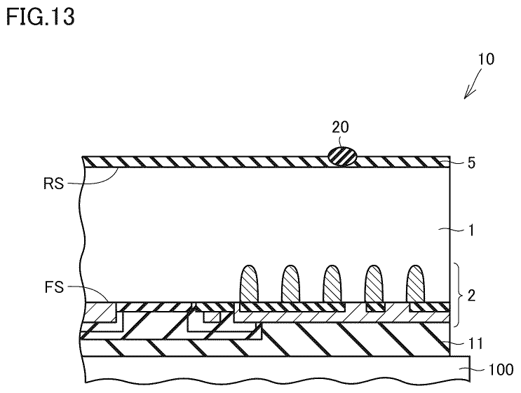

FIG. 13 is a cross-sectional view schematically illustrating an oxide film formation step of the manufacturing method of a semiconductor substrate according to the second embodiment.

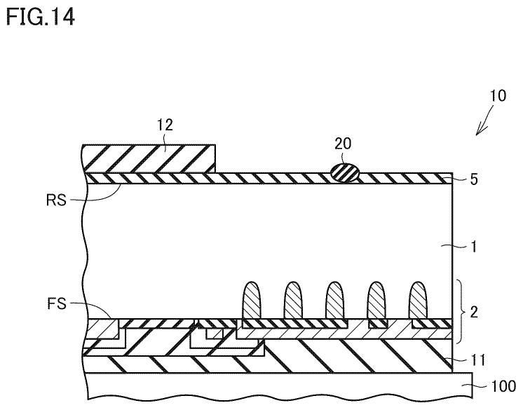

FIG. 14 is a cross-sectional view schematically illustrating a resist formation step included in the ion implantation step of the manufacturing method of a semiconductor substrate according to the second embodiment.

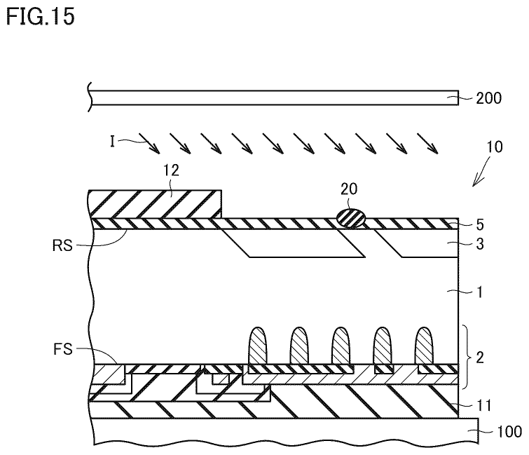

FIG. 15 is a cross-sectional view schematically illustrating that ion implantation is performed from a first direction in the ion implantation step of the manufacturing method of a semiconductor substrate according to the second embodiment.

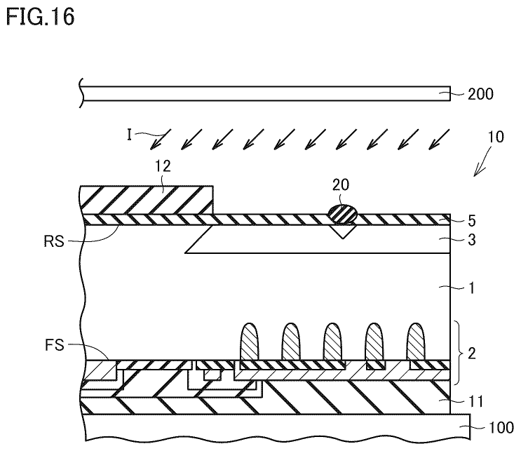

FIG. 16 is a cross-sectional view schematically illustrating that ion implantation is performed from a second direction in the ion implantation step of the manufacturing method of a semiconductor substrate according to the second embodiment.

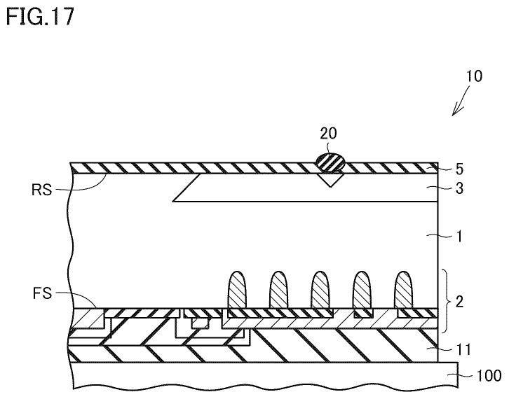

FIG. 17 is a cross-sectional view schematically illustrating a resist removal step included in the ion implantation step of the manufacturing method of a semiconductor substrate according to the second embodiment.

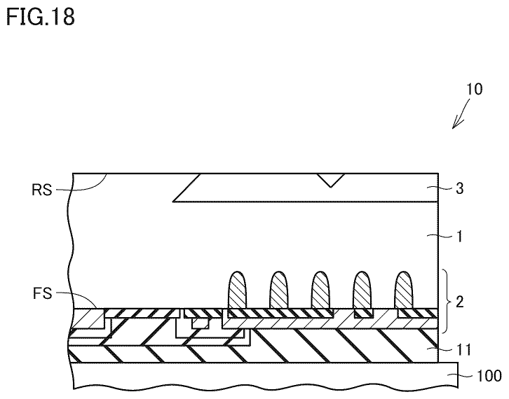

FIG. 18 is a cross-sectional view schematically illustrating an oxide film removal step of the manufacturing method of a semiconductor substrate according to the second embodiment.

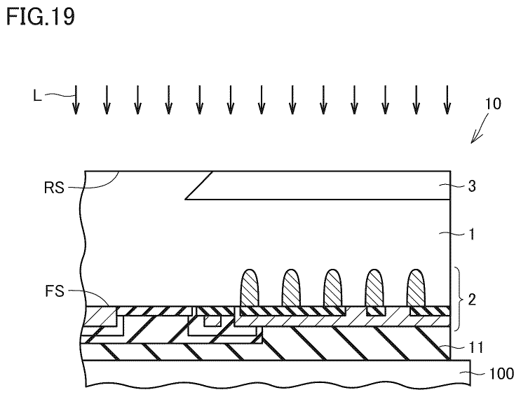

FIG. 19 is a cross-sectional view schematically illustrating an activation step of the manufacturing method of a semiconductor substrate according to the second embodiment.

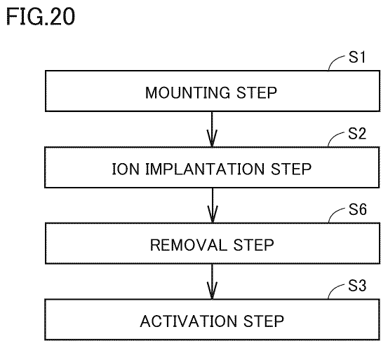

FIG. 20 is a flowchart illustrating a manufacturing method of a semiconductor substrate according to a third embodiment.

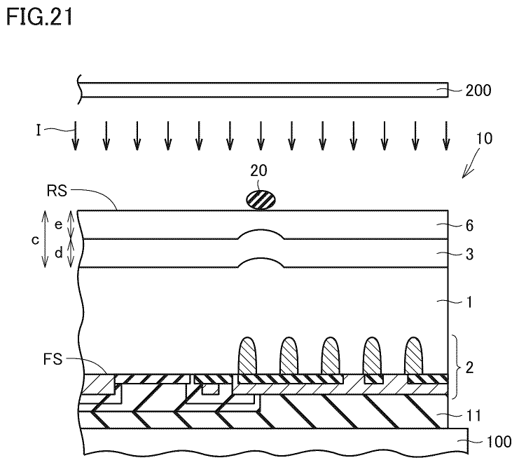

FIG. 21 is a cross-sectional view schematically illustrating an ion implantation step of the manufacturing method of a semiconductor substrate according to the third embodiment.

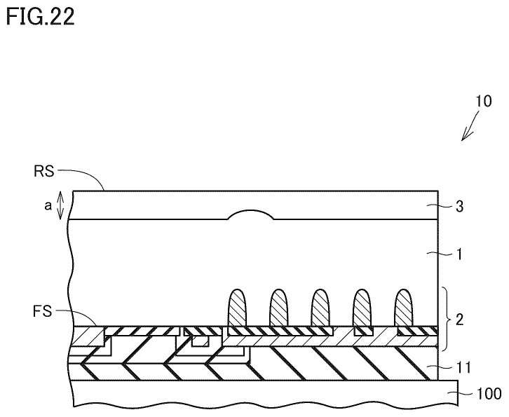

FIG. 22 is a cross-sectional view schematically illustrating a removal step of the manufacturing method of a semiconductor substrate according to the third embodiment.

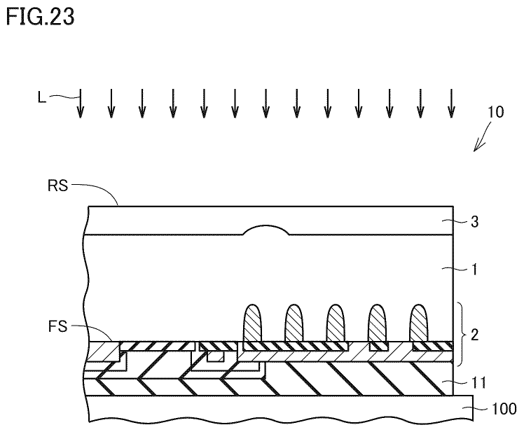

FIG. 23 is a cross-sectional view schematically illustrating an activation step of the manufacturing method of a semiconductor substrate according to the third embodiment.

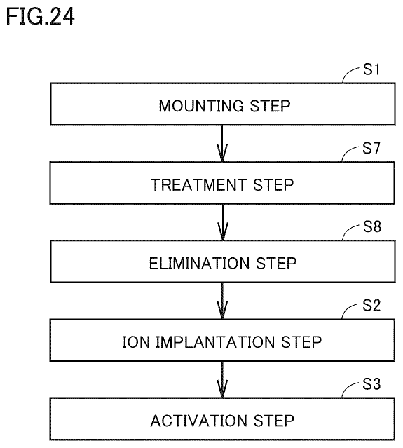

FIG. 24 is a flowchart illustrating a manufacturing method of a semiconductor substrate according to a fourth embodiment.

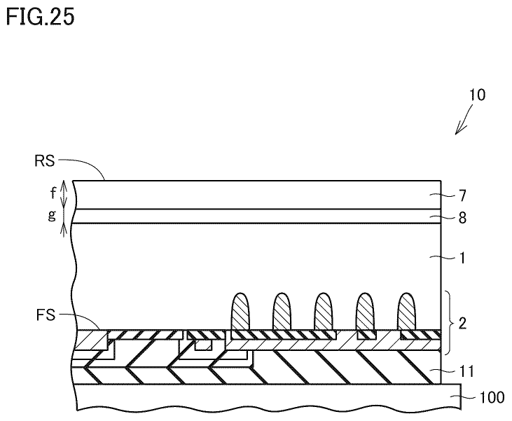

FIG. 25 is a cross-sectional view schematically illustrating a treatment step of the manufacturing method of a semiconductor substrate according to the fourth embodiment.

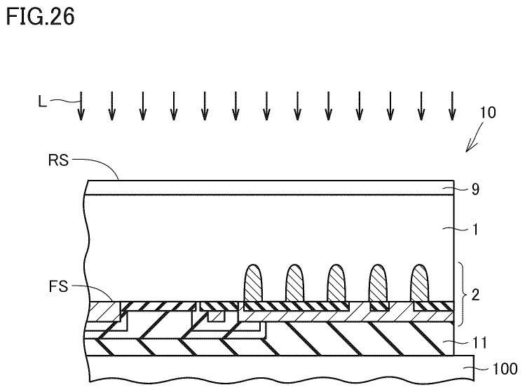

FIG. 26 is a cross-sectional view schematically illustrating an elimination step of the manufacturing method of a semiconductor substrate according to the fourth embodiment.

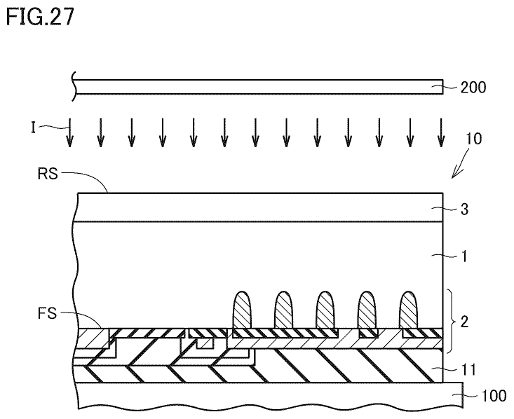

FIG. 27 is a cross-sectional view schematically illustrating an ion implantation step of the manufacturing method of a semiconductor substrate according to the fourth embodiment.

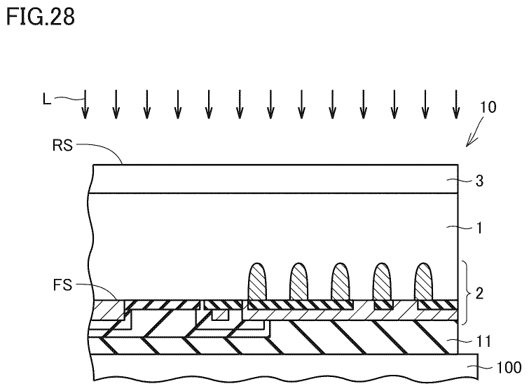

FIG. 28 is a cross-sectional view schematically illustrating an activation step of the manufacturing method of a semiconductor substrate according to the fourth embodiment.

### DESCRIPTION OF THE PREFERRED EMBODIMENTS

Hereinafter, embodiments will be described with reference to the drawings. In the following description, the same or corresponding portions will be denoted by the same reference numerals, and the description thereof will not be repeated.

### First Embodiment

A manufacturing method of a semiconductor substrate 10 according to the first embodiment will be described with reference to FIGS. 1 to 8. The manufacturing method of semiconductor substrate 10 according to the present embodiment is a method of forming an ion implantation layer on a rear surface in the rear surface wafer process of IGBT (Insulated Gate Bipolar Transistor).

As illustrated in FIG. 1, the manufacturing method of semiconductor substrate 10 according to the first embodiment includes a mounting step S1, an ion implantation step S2, and an activation step S3. The ion implantation step S2 includes a resist formation step S21, an ion implantation layer formation step S22, and a resist removal step S23.

As illustrated in FIG. 2, in the mounting step S1, a substrate body 1 has a front surface FS on which a front surface electrode 2 is formed and a rear surface RS which faces front surface FS. The material of substrate body 1 is, for example, silicon (Si). Front surface electrode 2 includes a gate electrode or the like, and substrate body 1 is mounted on a mounting stage 100 with rear surface RS facing upward. Semiconductor substrate 10 is mounted on mounting stage 100 with a protective film 11 interposed therebetween.

As illustrated in FIG. 3, in the ion implantation step S2, a resist formation step S21 is performed. In the resist formation step S21, a resist 12 for forming a rear surface pattern is formed on rear surface RS of substrate body 1. Resist 12 is formed by photolithography. Before the ion implantation is performed, a foreign substance 20 such as particles may adhere to rear surface RS of substrate body 1.

As illustrated in FIGS. 4 and 5, in the ion implantation step S2, an ion implantation layer formation step S22 is performed. In the ion implantation layer formation step S22, an ion implantation layer 3 is formed by performing ion implantation by irradiating an ion beam I from an ion implantation apparatus 200. In the ion implantation layer formation step S22, ion implantation layer 3 is formed by performing ion implantation on rear surface RS of substrate body 1 from a first direction and a second direction symmetrical to the first direction at an angle of 45° or more and 84° or less with respect to rear surface RS of substrate body 1 mounted on mounting stage 100. FIG. 4 illustrates that the ion implantation is performed on rear surface RS of substrate body 1 from the first direction. FIG. 5 illustrates that the ion implantation is performed on rear surface RS of substrate body 1 from the second direction.

Even when a foreign substance 20 is present on rear surface RS of substrate body 1, the ion implantation is performed in separate steps with different implantation angles, whereby ion implantation layer 3 is formed even under foreign substance 20. Ion implantation layer 3 is formed by implanting an n-type impurity such as phosphorus (P) or a p-type impurity such as boron (B).

As illustrated in FIG. 6, a width a of foreign substance 20 is the size of foreign substance 20 in the horizontal direction of substrate body 1. Since a foreign substance generally has a size of 1 μm or more and 10 μm or less, width a of foreign substance 20 is set to 1 μm or more and 10 μm or less. An implantation depth b of the ion implantation is set to 1 μm. When width a of foreign substance 20 is 1 μm, if implantation depth b is 1 μm, an implantation angle θ of the ion implantation is 45° (tan⁻¹(1/1)=45°). When width a of foreign substance 20 is 10 μm, if implantation depth b is 1 μm, implantation angle θ of the ion implantation is about 84° (tan⁻¹(10/1)=84.29°). Therefore, ion implantation layer 3 can be formed under foreign substance 20 by performing the ion implantation at an angle of 45° or more and 84° or less with respect to rear surface RS of substrate body 1.

As illustrated in FIG. 7, in the ion implantation step S2, a resist removal step S23 is performed. In the resist removal step S23, resist 12 is removed from rear surface RS of substrate body 1. Resist 12 is removed before a laser annealing treatment is performed. Foreign substance 20 is also removed at the same time.

As illustrated in FIG. 8, in the activation step S3, the ions implanted into ion implantation layer 3 are activated by performing a laser annealing treatment on ion implantation layer 3. Therefore, the ions are diffused to form a diffusion layer. Rear surface RS of substrate body 1 is irradiated with a laser beam L to undergo a high-temperature heat treatment, whereby a high impurity concentration region is formed without heating the pattern surface. The ions implanted into ion implantation layer 3 are activated, and thereby the characteristics of the device are maintained.

Ion implantation apparatus 200 used in the manufacturing method of semiconductor substrate 10 according to the first embodiment will be described with reference to FIG. 9.

Ion implantation apparatus 200 includes an ion source 201, a gas supply unit 202, an extraction electrode 203, a mass separator 204, an analysis slit 205, an acceleration tube 206, a deflector 207, a lens 208, and a scanner 209. Ion source 201 generates ions of a target element using a raw material gas supplied from gas supply unit 202. The ions generated by ion source 201 are extracted by extraction electrode 203. The ions extracted by extraction electrode 203 are separated by mass separator 204. The ions separated by mass separator 204 are selected by analysis slit 205. The ions selected by analysis slit 205 are accelerated by acceleration tube 206 to form an ion beam. Deflector 207 deflects the ion beam. Lens 208 shapes the ion beam. Scanner 209 controls the direction of the ion beam.

Ions from ion implantation apparatus 200 are implanted into rear surface RS of substrate body 1 of semiconductor substrate 10 mounted on mounting stage 100. Mounting stage 100 is rotatable. By rotating mounting stage 100, ion implantation is performed on rear surface RS of substrate body 1 of semiconductor substrate 10 from the first direction and the second direction.

The configuration of semiconductor substrate 10 according to the first embodiment will be described with reference to FIG. 10.

Semiconductor substrate 10 according to the first embodiment includes a substrate body 1, a front surface electrode 2, and a collector electrode 4. Substrate body 1 has a front surface FS and a rear surface RS which faces front surface FS. Front surface electrode 2 is formed on front surface FS. Collector electrode 4 is formed on rear surface RS. Substrate body 1 includes an element portion 1b and a terminal portion 1a. Element portion 1b is configured to allow a main current to flow therethrough. Termination portion 1a is disposed outside element portion 1b. Element portion 1b includes an ion implantation layer 3 formed on rear surface RS. Ion implantation layer 3 is formed at an angle of 45° or more and 84° or less with respect to rear surface RS.

Next, the effect of the first embodiment will be described.

According to the manufacturing method of semiconductor substrate 10 according to the first embodiment, in the ion implantation step, ion implantation layer 3 is formed by performing ion implantation rear surface RS of substrate body 1 from the first direction and the second direction symmetrical to the first direction at an angle of 45° or more and 84° or less with respect to rear surface RS of substrate body 1 mounted on mounting stage 100. Therefore, even if foreign substance 20 having width a of 1 μm or more and 10μm or less is present on rear surface RS of substrate body 1, ion implantation layer 3 can be formed under foreign substance 20 by performing the ion implantation from the first direction and the second direction. This ensures the formation of ion implantation layer 3 on rear surface RS of substrate body 1 of semiconductor substrate 10, which prevents the occurrence of a leakage current.

In the activation step S3, the ions implanted into ion implantation layer 3 are activated by performing a laser annealing treatment on ion implantation layer 3. Therefore, the ions are diffused to form a diffusion layer.

In semiconductor substrate 10 according to the first embodiment, ion implantation layer 3 is formed at an angle of 45° or more and 84° or less with respect to rear surface RS. Therefore, even if foreign substance 20 having width a of 1 μm or more and 10 μm or less is present on rear surface RS of substrate body 1, ion implantation layer 3 can be formed even under foreign substance 20 by performing the ion implantation from the first direction and the second direction. This ensures the formation of ion implantation layer 3 on rear surface RS of substrate body 1 of semiconductor substrate 10, which prevents the occurrence of a leakage current.

Hereinafter, a modification of the manufacturing method of semiconductor substrate 10 according to the first embodiment will be described with reference to FIG. 11.

In the modification of the manufacturing method of semiconductor substrate 10 according to the first embodiment, in the ion implantation step S2, ion implantation is performed by rotating mounting stage 100 so as to rotate substrate body 1. By rotating mounting stage 100, semiconductor substrate 10 mounted on mounting stage 100 can be rotated at an angle of 360° in the circumferential direction with respect to the center. Then, ion implantation can be performed by rotating semiconductor substrate 10.

According to the modification of the manufacturing method of semiconductor substrate 10 according to the first embodiment, in the ion implantation step S2, ion implantation is performed by rotating mounting stage 100 so as to rotate substrate body 1. Therefore, ion implantation can be performed at an angle of 360° in the circumferential direction with respect to the rotation center of semiconductor substrate 10. Therefore, ion implantation layer 3 can be formed under foreign substance 20. This ensures the formation of ion implantation layer 3 on rear surface RS of substrate body 1 of semiconductor substrate 10, which prevents the occurrence of a leakage current.

### Second Embodiment

The manufacturing method, the configuration and the effect of the second embodiment are the same as those of the first embodiment unless otherwise specified. Therefore, the same components as those of the first embodiment are denoted by the same reference numerals, and the description thereof will not be repeated.

The manufacturing method of a semiconductor substrate 10 according to the second embodiment will be described with reference to FIGS. 12 to 19.

As illustrated in FIG. 12, the manufacturing method of semiconductor substrate 10 according to the second embodiment includes a mounting step S1, an ion implantation step S2, an activation step S3, an oxide film formation step S4, and an oxide film removal step S5. In other words, the manufacturing method of semiconductor substrate 10 according to the second embodiment further includes an oxide film formation step S4 and an oxide film removal step S5. The oxide film formation step S4 is performed before the ion implantation step S2. The oxide film removal step S5 is performed after the ion implantation step S2.

As illustrated in FIG. 13, in the oxide film formation step S4, an oxide film 5 for trapping foreign substance 20 is formed on rear surface RS of substrate body 1 before the ion implantation step S2. Oxide film 5 is formed on the entire rear surface RS of substrate body 1.

As illustrated in FIG. 14, in the ion implantation step S2, a resist formation step S21 is performed. In the resist formation step S21, a resist 12 for forming a rear surface pattern is formed on oxide film 5.

As illustrated in FIG. 15, in the ion implantation step S2, an ion implantation layer formation step S22 is performed. In the ion implantation layer formation step S22, an ion implantation layer 3 is formed by performing ion implantation from the first direction at an angle of 45° or more and 84° or less with respect to rear surface RS of substrate body 1 mounted on mounting stage 100.

As illustrated in FIG. 16, subsequently, an ion implantation layer 3 is formed by performing ion implantation from the second direction at an angle of 45° or more and 84° or less with respect to rear surface RS of substrate body 1 mounted on mounting stage 100.

As illustrated in FIG. 17, in the ion implantation step S2, a resist removal step S23 is performed. In the resist removal step S23, resist 12 is removed from oxide film 5.

As illustrated in FIG. 18, in the oxide film removal step S5, oxide film 5 is removed together with the trapped foreign substance 20 after the ion implantation step S2. Oxide film 5 is removed from the entire rear surface RS of substrate body 1.

As illustrated in FIG. 19, in the activation step S3, the ions implanted into ion implantation layer 3 are activated by performing a laser annealing treatment on ion implantation layer 3 from rear surface RS of substrate body 1 from which oxide film 5 has been removed.

Next, the effect of the second embodiment will be described.

In the manufacturing method of semiconductor substrate 10 according to the second embodiment, in the oxide film removal step S5, oxide film 5 is removed together with the trapped foreign substance 20 after the ion implantation step S2. Therefore, foreign substance 20 can be removed by removing oxide film 5. In addition, by trapping foreign substance 20 before the ion implantation, it is possible to prevent foreign substance 20 from floating and adhering to another position again during the ion implantation. If foreign substance 20 adheres to another position again during the ion implantation, the position to which foreign substance 20 adheres becomes an ion non-implanted region, and thus it is possible to prevent the formation of an ion non-implanted region by preventing the re-adhesion of foreign substance 20.

### Third Embodiment

The manufacturing method, the configuration and the effect of the third embodiment are the same as those of the first embodiment unless otherwise specified. Therefore, the same components as those of the first embodiment are denoted by the same reference numerals, and the description thereof will not be repeated.

The manufacturing method of a semiconductor substrate 10 according to the third embodiment will be described with reference to FIGS. 20 to 23.

As illustrated in FIG. 20, the manufacturing method of semiconductor substrate 10 according to the third embodiment includes a mounting step S1, an ion implantation step S2, an activation step S3, and a removal step S6. The removal step S6 is performed between the ion implantation step S2 and the activation step S3.

As illustrated in FIG. 21, in the ion implantation step S2, ion implantation is performed on rear surface RS of substrate body 1 mounted on mounting stage 100 to form an ion implantation layer 3 spaced apart from rear surface RS. The implantation energy for performing ion implantation in the ion implantation step S2 is 5 times or more and 10 times or less the implantation energy for performing ion implantation from rear surface RS to a depth that is equal to the thickness of ion implantation layer 3. When the implantation energy for performing ion implantation from rear surface RS to a depth that is equal to the thickness of ion implantation layer 3 is 990 KeV, the implantation energy for performing ion implantation in the ion implantation step is 4950 KeV or more and 9900 KeV or less.

An implantation depth c of the ion implantation is the sum of a thickness d of ion implantation layer 3 and a thickness e of a portion 6 to be removed by at least one of an etching process and a grinding process in the removal step.

As illustrated in FIG. 22, in the removal step S6, a part of substrate body 1 from rear surface RS to ion implantation layer 3 is removed by at least one of an etching process and a grinding process.

As illustrated in FIG. 23, in the activation step S3, after the removal step S6, the ions implanted into ion implantation layer 3 are activated by performing a laser annealing treatment on ion implantation layer 3.

Next, the effect of the third embodiment will be described.

According to the manufacturing method of semiconductor substrate 10 according to the third embodiment, the implantation energy for performing ion implantation in the ion implantation step S2 is 5 times or more and 10 times or less the implantation energy for performing ion implantation from rear surface RS to a depth that is equal to the thickness of ion implantation layer 3. Therefore, by increasing the implantation energy for performing ion implantation, ions can be implanted across foreign substance 20. Therefore, ion implantation layer 3 can be formed under foreign substance 20. This ensures the formation of ion implantation layer 3 on rear surface RS of substrate body 1 of semiconductor substrate 10, which prevents the occurrence of a leakage current.

### Fourth Embodiment

The manufacturing method, the configuration and the effect of the fourth embodiment are the same as those of the first embodiment unless otherwise specified. Therefore, the same components as those of the first embodiment are denoted by the same reference numerals, and the description thereof will not be repeated.

The manufacturing method of a semiconductor substrate 10 according to the fourth embodiment will be described with reference to FIGS. 24 to 28.

As illustrated in FIG. 24, the manufacturing method of semiconductor substrate 10 according to the fourth embodiment includes a mounting step S1, an ion implantation step S2, an activation step S3, a treatment step S7, and an elimination step S8. The treatment step S7 is performed before the elimination step S8. The elimination step S8 is performed before the ion implantation step S2.

As illustrated in FIG. 25, in the treatment step S7, rear surface RS of substrate body 1 mounted on mounting stage 100 is treated by at least one of an etching process and a grinding process. In the present embodiment, a portion 7 to be removed is ground by a thickness f, and a portion 8 to be removed is etched by a thickness g.

As illustrated in FIG. 26, in the elimination step S8, a laser annealing treatment is performed on rear surface RS of substrate body 1 after the treatment step S7 to remove a foreign substance and a defect on rear surface RS. In a portion 9 heat-treated by a laser beam L, the foreign substance is baked by the heat of laser beam L. In addition, the defect of the portion 9 is heat-treated by laser beam L and is removed. In the elimination step S8, laser beam L is irradiated with an energy of about half the energy used to activate the ions in the activation step S3.

As illustrated in FIG. 27, in the ion implantation step S2, after the elimination step S8, ion implantation layer 3 is formed by performing ion implantation on rear surface RS of substrate body 1.

As illustrated in FIG. 28, in the activation step S3, the ions implanted into ion implantation layer 3 are activated by performing a laser annealing treatment on ion implantation layer 3.

Next, the effect of the fourth embodiment will be described.

According to the manufacturing method of semiconductor substrate 10 according to the fourth embodiment, in the elimination step S8, a laser annealing treatment is performed on rear surface RS of substrate body 1 after the treatment step S7, whereby a foreign substance and a defect on rear surface RS are removed. In the ion implantation step S2, after the elimination step S8, ion implantation layer 3 is formed by performing ion implantation on rear surface RS of substrate body 1. Therefore, ion implantation layer 3 can be formed uniform. This ensures the formation of ion implantation layer 3 on rear surface RS of substrate body 1 of semiconductor substrate 10, which prevents the occurrence of a leakage current.

The embodiments described above may be combined as appropriate.

It should be understood that the embodiments disclosed herein have been presented for the purpose of illustration and description but not limited in all aspects. It is intended that the scope of the present disclosure is not limited to the description above but defined by the scope of the claims and encompasses all modifications equivalent in meaning and scope to the claims.

What is claimed is:

1. A manufacturing method of a semiconductor substrate, the method comprising:
a mounting step of mounting a substrate body that has a front surface on which a front surface electrode is formed and a rear surface which faces the front surface on a mounting stage with the rear surface facing upward;
an ion implantation step of performing ion implantation on the rear surface of the substrate body mounted on the mounting stage from a first direction and a second direction symmetrical to the first direction at an angle of 45°or more and 84°or less with respect to the rear surface to form an ion implantation layer; and
an activation step of activating ions implanted into the ion implantation layer by performing a laser annealing treatment on the ion implantation layer.

2. The manufacturing method of a semiconductor substrate according to claim 1, wherein
in the ion implantation step, the ion implantation is performed by rotating the mounting stage so as to rotate the substrate body.

3. The manufacturing method of a semiconductor substrate according to claim 1, further comprising:
an oxide film formation step of forming an oxide film for trapping a foreign substance on the rear surface of the substrate body before the ion implantation step; and
an oxide film removal step of removing the oxide film together with the trapped foreign substance after the ion implantation step.

4. A semiconductor substrate comprising:
a substrate body that has a front surface and a rear surface which faces the front surface;
a front surface electrode formed on the surface; and
a collector electrode formed on the rear surface,
the substrate body including an element portion and a terminal portion disposed outside the element portion,
the element portion including an ion implantation layer formed on the rear surface, and
the ion implantation layer being formed at an angle of 45° or more and 84° or less with respect to the rear surface.

5. A manufacturing method of a semiconductor substrate, the method comprising:
a mounting step of mounting a substrate body that has a front surface on which a front surface electrode is formed and a rear surface which faces the front surface on a mounting stage with the rear surface facing upward;
an ion implantation step of performing ion implantation on the rear surface of the substrate body mounted on the mounting stage to form an ion implantation layer spaced apart from the rear surface;
a removal step of removing a part of the substrate body from the rear surface to the ion implantation layer by at least one of an etching process and a grinding process; and
an activation step of activating ions implanted into the ion implantation layer by performing a laser annealing treatment on the ion implantation layer after the removal step,
an implantation energy for performing ion implantation in the ion implantation step being 5 times or more and 10 times or less an implantation energy for performing ion implantation from the rear surface to a depth that is equal to a thickness of the ion implantation layer.

6. A manufacturing method of a semiconductor substrate, the method comprising:
a mounting step of mounting a substrate body that has a front surface on which a front surface electrode is formed and a rear surface which faces the front surface on a mounting stage with the rear surface facing upward;
a treatment step of treating the rear surface of the substrate body mounted on the mounting stage by at least one of an etching process and a grinding process;
an elimination step of eliminating a foreign substance and a defect on the rear surface of the substrate body by performing a laser annealing treatment on the rear surface after the treatment step;
an ion implantation step of performing ion implantation on the rear surface of the substrate body to form an ion implantation layer after the removal step; and
an activation step of activating ions implanted into the ion implantation layer by performing a laser annealing treatment on the ion implantation layer.
